(19) United States
(12) Patent Application Publication
(10) Pub. No.: US 2011/0120763 A1
(43) Pub. Date: May 26, 2011

(54) STRUCTURE AND METHOD OF FORMING A FILM THAT BOTH PREVENTS ELECTROMAGNETIC INTERFERENCE AND TRANSMITS AND RECEIVES SIGNALS

(75) Inventors: Pi-Hsi Cheng, Zhubei City (TW); Chung-Han Chen, Taoyuan City (TW); Chun-Yang Li, Zhudong Township (TW); Mao-Liang Tien, Taipei City (TW)

(73) Assignee: PARAGON TECHNOLOGIES Co., Ltd., Gueishan Township (TW)

(21) Appl. No.: 12/623,387

(22) Filed: Nov. 21, 2009

(51) Int. Cl. H05K 9/00; B05D 5/12; C23C 14/34; C23C 14/22; B32B 37/00

(52) U.S. Cl. 174/377; 427/58; 204/192.1; 427/523; 156/60

(57) ABSTRACT

The present invention is a film for prevention of electromagnetic interference and transmission of wireless signals. A conductive lamination is integrally attached to a preset position of a substrate and shaped as a film and a signal transceiver. The method of forming the film includes selecting a substrate and selecting a signal transmitting and receiving mode and a form of the conductive surface according to a specific need. A film-shaped signal transceiver and conductive lamination are integrally formed on a preset area of the substrate. By plating and/or coating, the present invention can form a conductive lamination on the substrate with both functions as a signal transceiver and a shield.

### CROSS-REFERENCE TO RELATED U.S. APPLICATIONS

Not applicable.

### STATEMENT REGARDING FEDERALLY SPONSORED RESEARCH OR DEVELOPMENT

Not applicable.

### NAMES OF PARTIES TO A JOINT RESEARCH AGREEMENT Not applicable.

### REFERENCE TO AN APPENDIX SUBMITTED ON COMPACT DISC Not applicable.

### BACKGROUND OF THE INVENTION

1. Field of the Invention

The present invention relates generally to a film used in communication electronic devices, and more particularly to an innovative film attached to a substrate with a transceiver and a conductive lamination.

2. Description of Related Art Including Information Disclosed Under 37 CFR 1.97 and 37 CFR 1.98.

With the rapid development of information technology and the Internet, electronic devices, such as notebook computers, PDAs, mobile phones, satellite navigation devices, have all introduced wireless transmission for the purpose of free communication and Internet access unlimited by space. As an important component to realize wireless transmission, the antenna plays a dominant role in the field of information technology.

To meet the current demand for thinner, lighter and smaller products, the sizes of all components in electronic devices must be as small as possible, and antennas are no exception. With the existing technology, antennas can be formed by three-dimensional frames and by generally two-dimensional foils. Therefore, minimization of size is not a problem. However, in the construction of electronic devices, there must consideration for the stability of antennas in transmitting and receiving signals. To avoid interference to signal transmitting and receiving by the magnetic wave generated during operation of the electronic components in the device, a separate shield metal is usually configured on the device. For example, in a notebook computer, a metal plate is conventionally fixed on the side the light-emitting diode (LED) panel inside the casing. Another solution is the application of a metal foil within the casing to solve the problem. However, such prior art practices are still too complicated, and production of related structures of the whole antenna have to undergo numerous processes. Such a shortcoming is obviously not intended to limit the development of the related electronics industry.

Thus, to overcome the aforementioned problems of the prior art, it would be an advancement in the art to provide an improved structure that can significantly improve efficacy. Therefore, the inventor has provided the present invention of practicability after deliberate experimentation and evaluation based on years of experience in the production, development and design of related products.

### BRIEF SUMMARY OF THE INVENTION

The present invention is an innovative and unique film integrally formed by a conductive lamination and a signal transceiver attached to the surface of a substrate. The present invention is an improvement over the conventional structures disclosed in the prior art. The signal transceiver and a conductive lamination as a metal shield can be formed at the same time on the substrate by means of plating, coating or printing to constitute a signal transmitting and receiving structure. Thus, the processes for manufacturing the signal transmitting and receiving structure for electronic devices can be greatly reduced. Hence, the present invention has increased productivity, reduced cost and provided effective shielding, as well as provided better economic benefits for the industry.

Although the invention has been explained in relation to its preferred embodiment, it is to be understood that many other possible modifications and variations can be made without departing from the spirit and scope of the invention as hereinafter claimed.

### BRIEF DESCRIPTION OF THE SEVERAL VIEWS OF THE DRAWINGS

FIG. 1 shows an upper perspective view of a preferred embodiment of the present invention.

FIG. 2 shows a schematic view of a preferred embodiment of the present invention.

FIG. 3 shows an isolated view of a preferred embodiment of the present invention.

FIG. 4 shows another schematic view of another embodiment of the present invention.

### DETAILED DESCRIPTION OF THE INVENTION

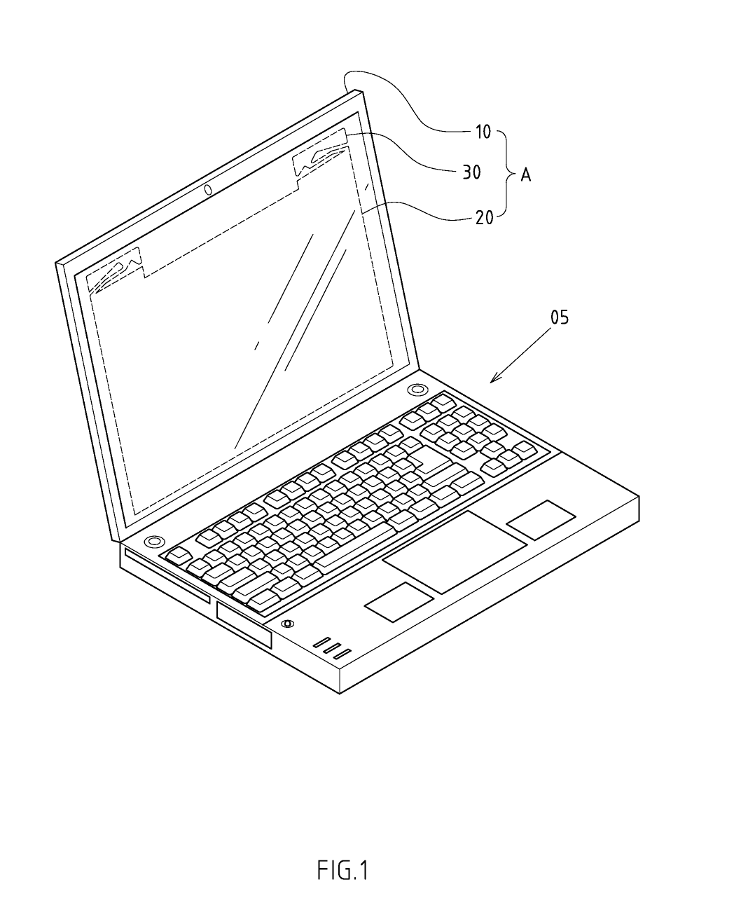

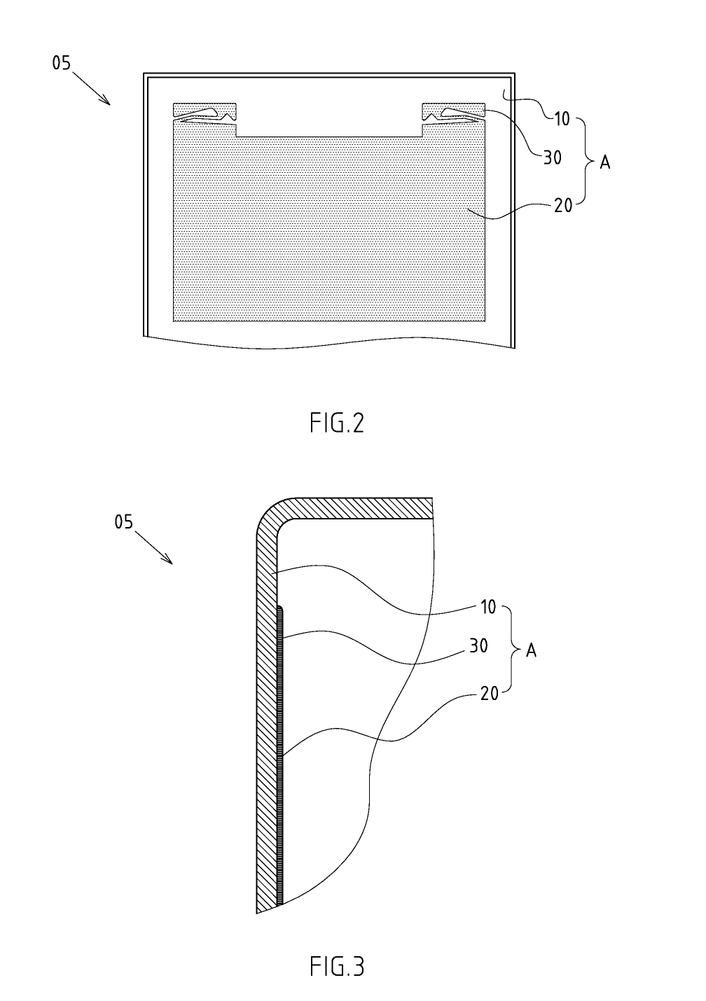

FIGS. 1 and 2 show a preferred embodiment of the present invention of the film for prevention of electromagnetic interference and transmission of wireless signals. The present embodiments are only shown for descriptive purposes. The scope of the invention is set by the claims.

The film structure A comprises a conductive lamination 20 and signal transceiver 30, which are integrally attached to a preset position on surface of a substrate 10. The conductive lamination 20 can be used as a metal shield of the electronic device 05 for the effect and purpose of blocking magnetic waves.

The substrate 10 can be the casing, enclosure or internal component (e.g. support frame, component substrate, etc.) of the electronic device 05. The substrate 10 is not limited to a planar surface and can also be defined as cambered surface, curved surface, or convex-concave surface. The electronic device 05 refers to all kinds of electronic devices, such as notebook computers, PDAs, mobile phones, satellite navigation devices, which have wireless capability.

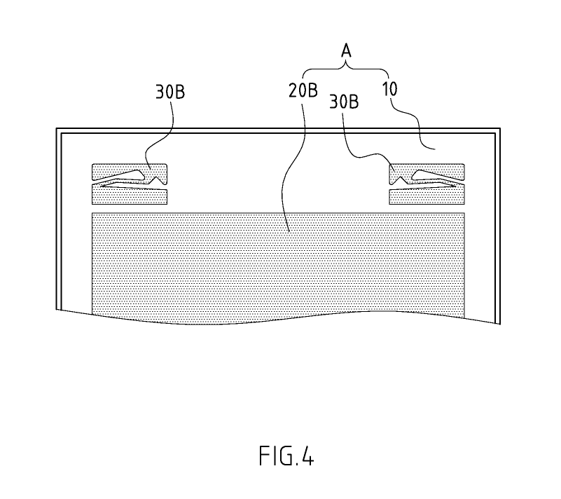

As shown in FIG. 2, the signal transceiver 30 and the conductive lamination 20 can be configured in the form of integral connection. Or, as shown in FIG. 4, the signal transceiver 30B and the conductive lamination 20B can be separated by a space.

The method of forming the film of the present invention comprises the steps of:
(a) selecting a substrate 10;
(b) selecting an antenna form and a conductive metal surface form according to a required frequency band; and
(c) attaching a film-shaped signal transceiver 30 and conductive lamination 20 on a preset area of the substrate 10.

The attachment can be by coating (e.g. sputtering, evaporation, wet plating, ion plating, chemical plating, silver mirror reaction, etc.), or spraying by which a substance can be attached to the surface of the substrate 10 and a metal film can be formed on the surface. In practice, manufacturers can choose a proper method according to the substrate material, the expected thickness and fineness of the metal film, as well as bond strength.

The thickness of the film of conductive lamination 20 and signal transceiver 30 is between 0.1˜10 m.

The conductive lamination 20 and signal transceiver 30 can be one-layer lamination or multi-layer lamination.

In actual application of the technology disclosed in the present invention, as shown in FIGS. 1, 2, and 3, the electronic device 05 is a notebook computer. The substrate 10 of the film structure A is the back part of the enclosure of the notebook computer on the side of the display panel. The conductive lamination 20 is configured in a rectangular shape, and the signal transceivers 30 are integrally connected to the side of the conductive lamination 20 and relatively distributed in two sets on the left and right with a space of separation. Thus, the surface-shaped metal foil structure of the conductive lamination 20 can substitute existing plate-shaped shield metal to block electromagnetic waves and prevent ESD (electrostatic discharge). The signal transceiver 30 is located above the conductive lamination 20 for optimum signal transmitting and receiving effect.

We claim:

1. A film for prevention of electromagnetic interference and transmission/receiving of wireless signals, said film comprising:
a conductive lamination and a signal transceiver, being integrally formed at a preset position of a substrate and being film-shaped as a film, the conductive lamination and signal transceiver having a shielding function and a transmission/receiving function.

2. The film defined in claim 1, wherein said substrate is formed by an enclosure or internal component of an electronic device.

3. The film defined in claim 2, wherein the electronic device is selected from a group consisting of: notebook computers, PDAs, mobile phones, satellite navigation devices, and other devices with wireless communication.

4. The film defined in claim 1, wherein the signal transceiver and the conductive lamination are integrally connected.

5. The film defined in claim 1, wherein the signal transceiver and the conductive lamination are separated by a space and/or disconnected.

6. The film defined in claim 1, having a thickness of the conductive lamination and signal transceiver between 0.1-10 m.

7. The film defined in claim 1, wherein the conductive lamination and signal transceiver are formed by one-layer lamination or multi-layer lamination.

8. A method of forming a film for prevention of electromagnetic interference and transmission/receiving of wireless signals, the method comprising the steps of:
selecting a substrate;
selecting a signal transmitting and receiving mode and a form of the conductive surface according to a required frequency band; and
forming a film-shaped signal transceiver and conductive lamination on a preset area of the substrate, the conductive lamination and signal transceiver having a shielding function to block electromagnetic waves and/or prevent ESD (electrostatic discharge), as well as a function to transmit and receive signals.

9. The method defined in claim 8, wherein the step of forming comprises:
coating by sputtering or evaporation.

10. The method defined in claim 8, wherein the step of forming comprises:
plating by wet plating, ion plating, or chemical plating.

11. The method defined in claim 8, wherein the step of forming comprises:
spraying or silver mirror reaction.

12. The method defined in claim 8, wherein the substrate is formed by an enclosure or internal component of the electronic device.

13. The method defined in claim 12, wherein the electronic device refers to one selected from a group consisting of notebook computers, PDAs, mobile phones, satellite navigation devices, and other devices with a function of wireless communication.

14. The method defined in claim 8, wherein the signal transceiver and the conductive lamination are integrally connected.

15. The method defined in claim 8, wherein the signal transceiver and the conductive lamination are separated by a space and/or disconnected.

16. The method defined in claim 8, wherein the conductive lamination and signal transceiver have a thickness between 0.1-10 m.

17. The method defined in claim 8, wherein the conductive lamination and signal transceiver are formed by one-layer lamination or multi-layer lamination.
